(19) United States
(12) Patent Application Publication
(10) Pub. No.: US 2015/0262896 A1
(43) Pub. Date: Sep. 17, 2015

(54) EVALUATION ELEMENT AND WAFER

(71) Applicant: KABUSHIKI KAISHA TOSHIBA, Tokyo (JP)

(72) Inventors: Takaya YAMANAKA, Yokkaichi Mie (JP); Akira YOTSUMOTO, Yokkaichi Mie (JP)

(21) Appl. No.: 14/560,531

(22) Filed: Dec. 4, 2014

Related U.S. Application Data
(60) Provisional application No. 61/951,310, filed on Mar. 11, 2014.

(51) Int. Cl. H01L 21/66; H01L 29/78; H01L 23/00; H01L 23/522; H01L 23/528; H01L 29/66; H01L 21/768

(52) U.S. Cl. CPC H01L 22/32; H01L 29/66477; H01L 29/78; H01L 21/76802; H01L 21/76877; H01L 23/5226; H01L 23/528; H01L 24/09; H01L 24/03; H01L 2924/1443

(57) ABSTRACT

An evaluation element includes a plurality of first wirings extending in a first direction, connection conductors, each connection conductor electrically contact a single one of the first wirings, and a plurality of second wirings extending in a second direction that crosses the first direction and electrically contacts the connection conductors contacting the first wirings. The connection conductors are provided in at least two separated positions on the same first wiring. The plurality of second wiring are positioned such that a series electrical connection is established, through the connection conductors and the first wirings, between one second wiring and another second wiring.

### CROSS-REFERENCE TO RELATED APPLICATION

This application is based upon and claims the benefit of priority from U.S. Provisional Patent Application No. 61/951,310, filed Mar. 11, 2014, the entire contents of which are incorporated herein by reference.

### FIELD

Exemplary embodiments herein relate to an evaluation element and a wafer.

### BACKGROUND

In the process of manufacturing a semiconductor device, when forming a contact between wiring layers, an evaluation element is simultaneously manufactured on the wafer, and is used to evaluate whether or not a contact in the device under manufacture is electrically connected to an adjacent wiring layer. For example, an evaluation element may be configured to connect a region having a line and space pattern and a metal wiring layer spaced from, and extending in the same direction, as the space and line pattern using a interconnecting contact, which mimics a structure in an actual device. The evaluation device is then tested to determine whether or not the contact is electrically connected between the space and line pattern and the wiring layer by detecting a current value therethrough when the semiconductor region, contact, and metal wiring are connected in series.

Here, there maybe cases where the electrical connection of the contact may not be correctly detected as a result of the layout of the evaluation element.

### BRIEF DESCRIPTION OF THE DRAWINGS

FIG. 1 is an example of a plan view illustrating the arrangement state of an evaluation element in a first embodiment.

FIG. 2 is an example of a plan view illustrating the layout of the evaluation element.

FIG. 3A is an example of a longitudinal cross-sectional side view of a part taken along the line 3A-3A in FIG. 2.

FIG. 3B is an example of a longitudinal cross-sectional side view of a part taken along the line 3B-3B in FIG. 2.

FIG. 3C is an example of a longitudinal cross-sectional side view of a part taken along the line 3C-3C in FIG. 2.

FIG. 4 is an example of a plan view illustrating the arrangement state of an evaluation element in a second embodiment.

FIG. 5 is an example of a plan view illustrating the layout of the evaluation element.

FIG. 6A is an example of a cross-sectional view of a part taken along line 6A-6A in FIG. 5.

FIG. 6B is an example of a cross-sectional view of a part taken along line 6B-6B in FIG. 5.

FIG. 7 is an example of a plan view illustrating the layout of an evaluation element in a third embodiment.

FIG. 8 is an example of a plan view illustrating the layout of an evaluation element in a fourth embodiment.

FIG. 9 is an example of a plan view illustrating the layout of an evaluation element in a fifth embodiment.

FIG. 10 is an example of a plan view illustrating the layout of an evaluation element in a sixth element.

### DETAILED DESCRIPTION

According to one embodiment, an evaluation element includes a plurality of first wirings extending in a first direction, connection conductors, each connection conductor electrically contact a single one of the first wirings, and a plurality of second wirings extending in a second direction that crosses the first direction and electrically contacts the connection conductors contacting the first wirings. The connection conductors are provided in at least two separated positions on the same first wiring. The plurality of second wiring are positioned such that a series electrical connection is established, through the connection conductors and the first wirings, between one second wiring and another second wiring.

### First Embodiment

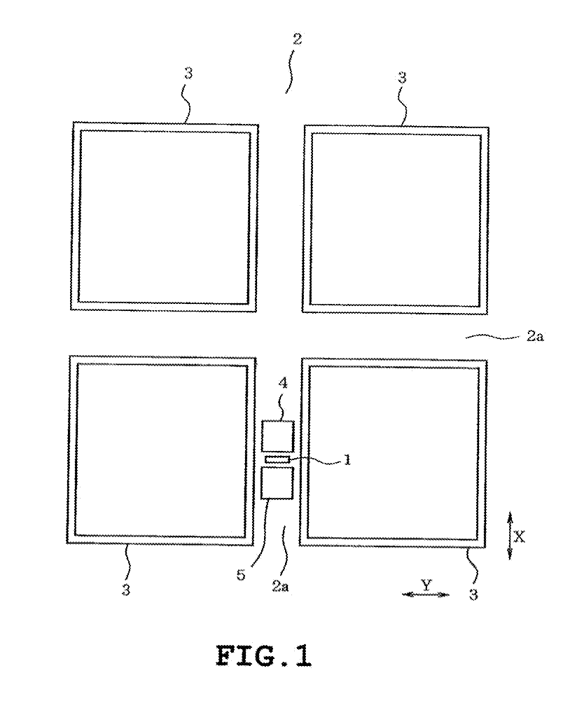

Below, the application of an evaluation element of a NAND flash memory device as a first embodiment will be described with reference to FIGS. 1 to 3. The drawings are merely schematic, and the relationship between thickness and planar dimension, the ratio between the thickness of each layer, and the like do not necessarily match those in actual practice. The vertical and horizontal directions indicate relative directions with the circuit forming surface side on a semiconductor substrate, described later, being the up side, and do not necessarily match the direction of gravitational acceleration as a standard.

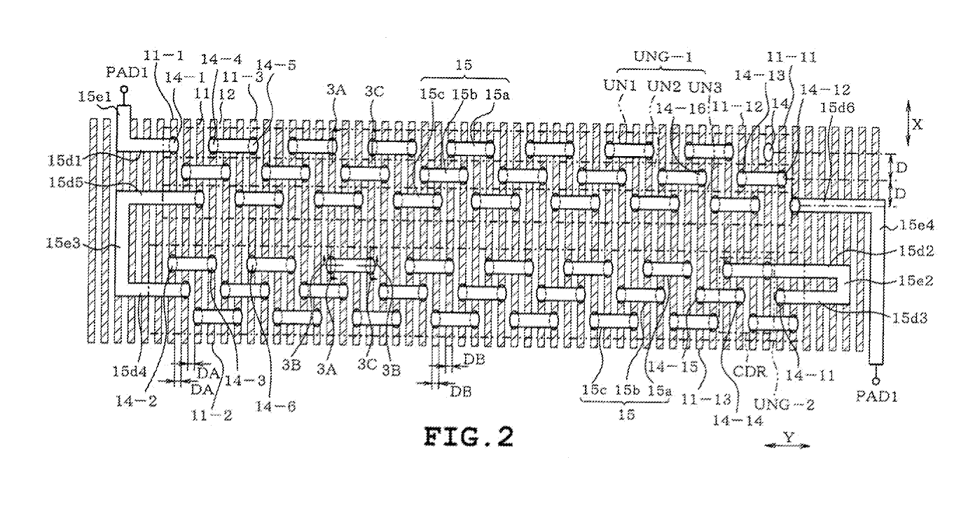

FIG. 1 illustrates an example of a layout pattern of an evaluation element 1 according to the first embodiment. The evaluation element 1 is arranged in the scribe region 2a of a semiconductor substrate such as a semiconductor wafer 2 between the locations where semiconductor devices 3 are formed on the semiconductor wafer 2. Numerous semiconductor devices 3 are manufactured in a matrix form on the semiconductor wafer 2. The semiconductor devices 3 are, for example, NAND flash memory devices. Since the evaluation element 1 is for evaluating one connection configuration (such as a wiring connection configuration) included in the semiconductor element 3 or the manufacturing process, the evaluation element mimics the connection configuration to be evaluated and is thus useful to evaluate the electrical or physical properties of the same connection configuration on the semiconductor device. In order to electrically evaluate the results of the manufacturing process, two electrode pads 4 and 5 for contact of a probe therewith are arranged on both sides of the evaluation element 1 located in the scribing region 2a. In FIG. 2, the electrode pads 4 and 5 are indicated by PAD 1 and PAD 2, respectively. Although four semiconductor devices 3 are illustrated in FIG. 1, the semiconductor devices 3 may be formed in greater numbers in and on the surface on the semiconductor wafer 2. One evaluation element 1 may be provided on the semiconductor wafer, or a plurality may be provided.

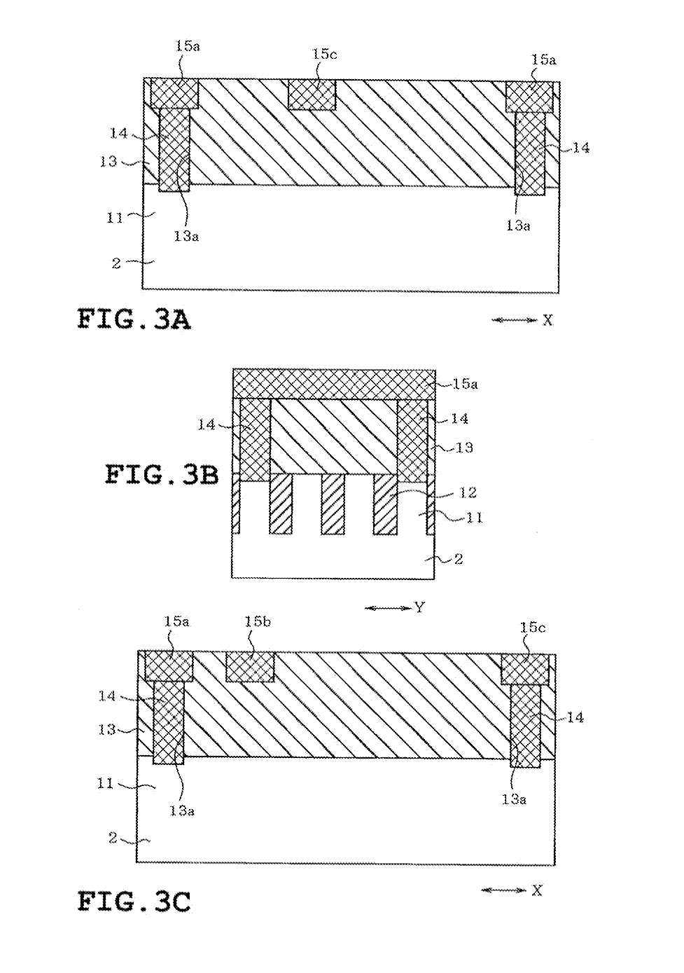

Next the specific configuration of the evaluation element 1 will be described with reference to FIG. 2 and FIGS. 3A to 3C. FIG. 2 is a plan view illustrating the layout of an evaluation element 1. FIGS. 3A to 3C are examples of cross-sections taken along lines 3A-3A, 3B-3B, and 3C-3C, respectively, in FIG. 2. A line-and-space pattern with a pattern width (for example, 20 nm) of the optical exposure limit of a photolithography technology or less is formed on the surface of the semiconductor wafer 2. That is, a plurality of element forming regions 11 is formed as a first wiring. Such element forming regions 11 may be formed using, for example, a sidewall transfer lithography technology. Multiple element forming regions 11 are formed and are spaced apart in the Y direction (second direction) by a predetermined gap, which gap is provided by an element separation region 12 formed by embedding an insulating film in a groove extending inwardly into the semiconductor wafer 2 and in the X direction therealong. As a result, the element forming regions 11 are provided having a width DB on the surface of the semiconductor wafer 2, and extend in the X direction (first direction), and neighbor each other with a distance DA therebetween in the Y direction.

An interlayer insulating film 13 is formed on the upper surface of the element forming region 11 (refer to FIGS. 3A to 3C). A contact plug 14 penetrates vertically through the interlayer insulating film 13. Contact plugs 14 that neighbor one another in the Y direction are configured as units UN1 to UN3, and one unit group UNG is configured with the units UN1 to UN3. In FIG. 2, two unit groups UNG-1 and UNG-2 are arranged. In the X direction, the distance between the centers of the contact plugs 14 that belong to each of the units UN1 to UN3 is indicated as a distance D. The contact plugs 14 that are adjacent to each other in the Y direction are separated by the distance DA in the Y direction. The contact plugs 14 on six element forming regions 11 that are adjacent to each other in the Y direction are made a unit, and the units are repeatedly arranged in the Y direction. The contact plug 14 is formed by embedding a conductor in a contact hole 13a. The conductor that configures the contact plug 14 has an oval shape when viewed from a direction that intersects the XY plane, and is arranged such that the long axis direction is aligned with the X direction. A metal material, such as tungsten that is a conductive material, a semiconductor material, such as silicon, or a material, such as a silicide, may be used as for the conductor of the contact plug 14.

A wiring pattern 15 as a second wiring is arranged so as to contact the upper surface of the contact plug 14 where it penetrates the upper surface of the interlayer insulating film 13. The wiring pattern 15 is configured as a plurality of wiring segments that extend over, and contact, two or more connection conductors where the connection conductors emerge from the insulating layer, and the pattern of segments extends in the Y direction such that the upper surface thereof is flush or co-planar with the upper surface of the interlayer insulating film 13, i.e., they are embedded inwardly of the insulating film so as to mimic a portion of a contact and line structure found in a dual damascene contact structure. In the first embodiment, the individual segments of the wiring pattern 15 electrically connect pairs of contact plugs 14 adjacent to each other in the Y direction. Along each span of segments of wiring portion extending in a generally straight line path in the Y direction, a contact plug 14 is disposed on every third element forming region 11. The contact plugs 14 adjacent to each other in the Y direction are formed in element forming regions 11 separated by two intervening element forming regions 11. Accordingly, the wiring pattern 15 is, if the pattern is properly formed, connected to a contact plug extending to every third element forming region 11 as illustrated in FIG. 3B. The location of the contact plugs 14 on adjacent element forming regions 11 is shifted by the distance D in the X direction, i.e., on the next element isolation region to the right in FIG. 2, the contact plug 14 is shifted in the X direction by distance X, and the contact plug 14 formed on the yet next element isolation region 11 to left in FIG. 2, the contact plug is shifted one further distance D in the X direction, such that the contact plugs that are adjacent to each other in a generally straight line path in the Y direction are separated by two intervening element forming regions 11 (distance DA×3+width DA×2). As a result, the wiring pattern may be formed without using sidewall transfer lithography technology, i.e., the feature size of the wiring layer segments is within the range of focus of non-sidewall transfer lithography and can thus be formed using a single patterned resist layer.

A plurality of wiring patterns 15a, 15b, and 15c are arranged extending in the Y direction with respect to each of the units UN1 to UN3 spaced from each other by the distance D in the X direction. Here, the wiring patterns 15a, 15b, and 15c spaced in the X direction are considered the upper, middle, and lower wiring patterns, respectively, and each such wiring pattern is configured as a plurality of segments extending in the Y direction, and spaced from each other in the Y direction.

On one element forming region 11, at least two contact plugs 14 are formed with a predetermined gap therebetween in the X direction. The two contact plugs 14 belong to separate unit groups UNG. As a result, as illustrated in FIGS. 3A and 3C, the contact plugs 14 belonging to different unit groups UNG are electrically connected via the element forming region 11.

The PAD 1 (electrode pad 4) and PAD 2 (electrode pad 5) are connected to the evaluation element 1. The PAD 1 is connected to a wiring pattern segment 15e1 which extends in the X direction, via a further wiring pattern, not illustrated. The wiring segments of the upper wiring patterns 15a, 15b and 15c along with the contact plugs and element formation regions, are electrically interconnected to provide an electrical path interconnecting first, second and third units of unit group one UNG-1 with the corresponding first, second and third units of unit group two UNG-2. Thus, the wiring pattern 15e1 is connected to one end of a wiring pattern segment 15d1 that extends in the Y direction and is connected to a contact plug 14-1 in unit one UN1 of unit group one UNG-1 arranged at the other end portion in the Y direction of the wiring pattern segment 15d1. The contact plug 14-1 is electrically connected to the upper wiring pattern 15a of the corresponding unit one UN1 of unit group two UNG-2 through the element forming region 11-1 and the contact plug 14-2 formed in the unit group UNG-2. The next segment of the upper wiring pattern 15a extends in the Y direction from contact plug 14-2 and is connected to a contact plug 14-3 formed on a third element forming region 11-2 in unit one UN1 of unit group two UNG-2, and is connected to the upper wiring pattern 15a in unit one UN1 of unit group one UNG-1 through the third element forming region and the contact plug 14-4 formed thereon in unit group UNG-1.

Similarly, the segments of the upper wiring pattern 15a are alternately electrically connected through contact plugs 14 and element forming regions 11 to go to and return from the unit groups UNG-1 and UNG-2, such as contact plug 14-5, element forming region 11-3, contact plug 14-6, etc . . . . Owing to this, the contact plugs 14 belonging to the unit UN1 of the unit groups UNG-1 and UNG-2 are connected in series via the element forming region 11 and the upper wiring pattern 15a.

In the opposite end portion side to the PAD 1 in the Y direction of the unit UN1 of the unit group UNG-2, the upper wiring pattern 15a is connected to a wiring pattern segment 15d2 extending in the Y direction. The wiring pattern 15d2 is connected to a wiring pattern 15d3 formed so as to fold back in the Y direction via a wiring pattern 15e2 extending in the X direction. The wiring pattern segment 15d3 is connected to a contact plug 14-11 of the unit UN2 in the unit group UNG-2. The contact plug 14-11 is connected, through element forming region 11-11 and the contact plug 14-2, to the middle wiring pattern 15b formed in the unit UN2 of the unit group UNG-1. The middle wiring pattern 15b is connected to a contact plug 14-13 formed in a third element forming region 11-12 positioned in the Y direction, and is connected to the middle wiring pattern 15b through the contact plug 14-14 formed in the unit UN2 of the unit group UNG-2 and the element forming region 11-12.

As with the connection of the upper wiring pattern in first unit UN1 of units groups one and two (UNG1 And UNG2), the segments of the middle wiring pattern 15b is alternately electrically connected back and forth between the unit groups UNG-1 and UNG-2, such as by the connection of the contact plug 14-15, the element forming region 11-13, the contact plug 14-16 etc., . . . . Owing to this, the contact plugs 14 belonging to the unit UN2 of the unit groups UNG-1 and UNG-2 are interconnected in series via the element forming region 11 and the middle wiring pattern 15b.

At the end portion of the evaluation element in the Y direction of the unit UN2 of the unit group UNG-2 adjacent to PAD 1, the middle wiring pattern 15b is connected to a wiring pattern 15d4 extending in the Y direction. The wiring pattern 15d4 is connected to a wiring pattern segment 15d5 formed so as to fold back in the Y direction via a wiring pattern 15e3 extending in the X direction. The wiring pattern segment 15d5 is connected to a contact plug 14 of the unit UN3 in the unit group UNG-1 at the end thereof in the Y direction.

Similarly to the above description, in each unit UN3 of the unit groups UNG-1 and UNG-2, the lower wiring pattern 15c is alternately electrically connected while going back and forth between the unit groups UNG-1 and UNG-2, through connected contact plugs 14, the element forming regions 11 and contact plugs 14 and the segments of the wiring patterns 15c . . . . Owing to this, the contact plugs 14 belonging to the unit UN3 of the unit groups UNG-1 and UNG-2 are connected in series via the element forming region 11 and the segments of the lower wiring pattern 15c.

Through the above, the three wiring level patterns 15a, 15b, and 15c are connected to the contact plugs 14 and the element forming regions 11, connected to a wiring pattern 15e4 bent in the X direction from a wiring pattern 15d6 positioned in the Y direction on the termination portion, and finally connected to the PAD 2.

<Unopening Evaluation of Contact Hole with Evaluation Element>

The evaluation element 1 can be used to determine whether the contact holes 13a were properly etched down to the level of the element formation regions 11, to determine the presence of one or more unopened contact holes (not opened down to the element formation regions 11) by determining whether or not the contact plugs 14 embedded in the contact holes 13 are electrically connected across the element isolation regions 11. To test the evaluation element 1, probes are brought into contact with the PAD 1 (electrode pad 4) and PAD 2 (electrode pad 5) from outside. For example, a positive voltage is applied to the PAD 1, and a lower voltage than that applied to the PAD 1 (for example, 0V) is applied to the PAD 2. Owing to this, the current flowing between the PAD 1 and PAD 2 is monitored. In this case, if the contact holes 13a of the interlayer insulating film 13 are properly formed, the contact plugs 14 are electrically connected to the element forming region 11 and the wiring pattern 15. Accordingly, since there is an electrically connected state between the PAD 1 and the PAD 2, the resistance value between the PAD 1 and PAD 2 enters a prescribed range. As a result, the current value is detected within a prescribed level indicating that the contact holes 13a are properly formed.

However, for example, when even one contact hole 13a formed in the interlayer insulating film 13 is unopened, for example, when the interlayer insulating film 13 is not reliably penetrated vertically during the etching of the contact holes 13a, the element forming region 11 and the wiring pattern 15 are electrically disconnected. As a result, the current value of a current that flows between the PAD 1 and the PAD 2 becomes lower than a prescribed value. That is, the contact plug 14 is not normally formed when any contact hole 13a of the conduction path in which it is formed is unopened, the current value deviates from the prescribed value, and a defect (unopened contact hole 13 somewhere in the evaluation element 1) may be detected. An unopened contact hole 13 in the evaluation element is an indication that similar contact holes in an adjacent semiconductor device being formed on the wafer may also be unopened, and thus the resulting manufactured device may be defective.

According to the first embodiment, with respect to the element forming regions 11 which provide the plurality of first wirings formed extending in the X direction, the evaluation element 1 is configured by providing the wiring pattern 15 as a second wiring extending in the Y direction on the upper surface of the insulating layer 13 with the contact plugs 14 interposed therebetween. The wiring pattern 15 may be patterned from a metal film with a pattern able to be optically exposed with non-sidewall transfer lithography technology, that is, the width of the wiring pattern 15 may be set to the width of the exposure limit of the exposure device or higher. The width in the X direction of the wiring pattern 15 is larger than the width in the Y direction of the element forming region 11, and is smaller than the distance D between the contact plugs 14 in the X direction. However, by connecting the segments of the wiring pattern 15 to a contact plug 14 connected to every third element forming region, the length of the wiring pattern 15 segments in the Y direction is not constrained by the spacing between adjacent element forming regions 11, and thus the length of the wiring pattern 15 segments is large enough to be optically patterned into a resist layer used to etch a metal film into individual wiring layer 15 segments. Thus two contact plugs 14 on every three element forming regions 11 may be connected in the Y direction to one wiring pattern 15. Thus, even if one wiring (the element formation region 11) is formed with a smaller width than the exposure limit, and the other wiring (wiring pattern 15) is formed with a width at the exposure limit or higher, the contact plugs 14 in the evaluation element 1 may still be connected in series . In other words, there are no portions at which the contact plugs 14 in the evaluation element 1 are connected in parallel. As a result, the formation state and the like of the contact plug 14 in the interlayer insulating film 13 may be accurately evaluated, by detecting the current value between the PAD 1 and the PAD 2.

In the embodiment, a pattern in which three contact plugs 14 on adjacent element forming regions 11 spaced in the Y direction are shifted in the X direction is considered a pattern unit CDR, and this one unit is repeated spaced in the Y direction, all of the contact plugs 14 in the evaluation element 1 may be connected in series. Here, when the contact plug 14 of the semiconductor element 3 includes the pattern unit CDR, evaluation suited to the pattern of an actual manufactured product may be performed by using the evaluation element 1.

One each of the contact plugs 14 in the pattern unit CDR are located in each of units UN1 to UN3, and thus the contact plugs 14 in the pattern unit CDR are connected to the wiring patterns 15a, 15b, and 15c, respectively, and the units UN1 to UN3 of unit group one UNG-1 and unit group two UNG-2 are connected by a folded-back wiring formed from the wiring patterns and segments 15d2, 15e2, and 15d3. As a result, the contact plugs 14 of the three divided units UN1 to UN3 may be connected in series, and a conductivity evaluation of the contact plugs 14 in all of the units UN1 to UN3 maybe performed with one detection operation, to determine if one of the contact plugs 14 is not connected to an underlying element forming region 11.

### Second Embodiment

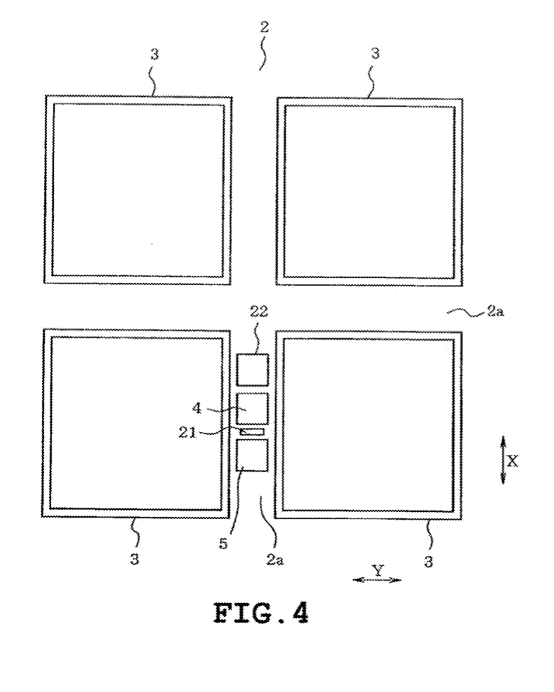

FIGS. 4 to 6B illustrate the second embodiment. Hereinafter, portions of the second embodiment which are different from the first embodiment will be described. In this embodiment, an evaluation element 21 with a configuration in which a gate electrode is provided in the configuration for electrically disconnecting the portions of the element forming region 11s to either side of the overlying gate electrode according to the wiring pattern layout of the first embodiment is configured

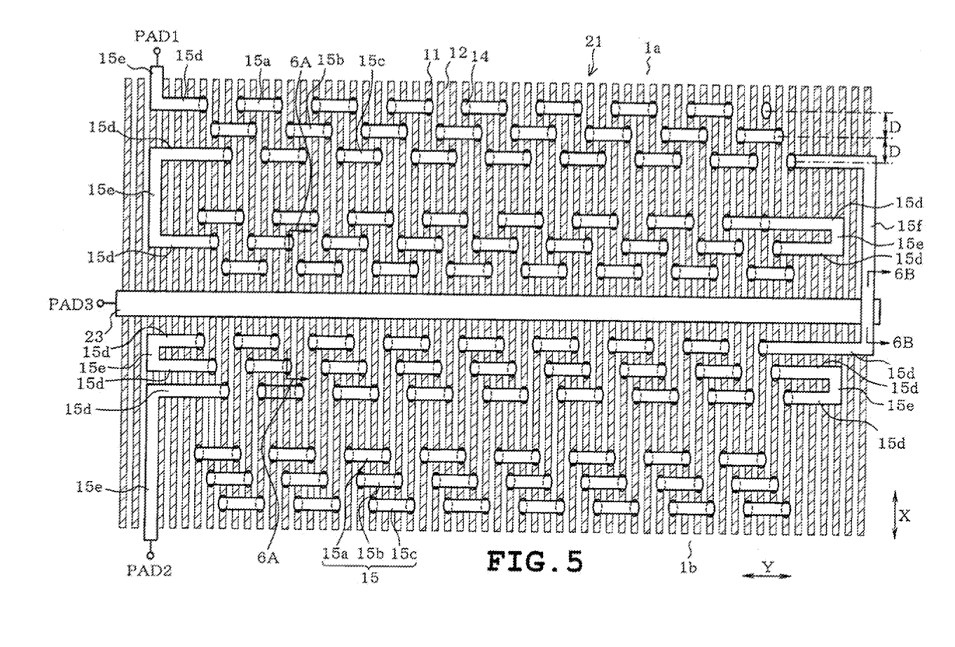

FIG. 4 illustrates an example of a layout pattern of the evaluation element 21. The evaluation element 21 is located in a scribing region 2a of a semiconductor wafer 2 in which numerous semiconductor devices 3 are arranged in a matrix pattern. In this embodiment, in order to electrically determine the presence of one or more unopened contact holes 13a, an electrode pad 22 is arranged in addition to the two electrode pads for contact of a probe 4 and 5 on both sides of the evaluation element 21 in the scribing region 2a. In FIG. 5, the electrode pad 4, the electrode pad 5 and the electrode pad 22 are indicated by PAD 1, PAD 2, and PAD 3, respectively.

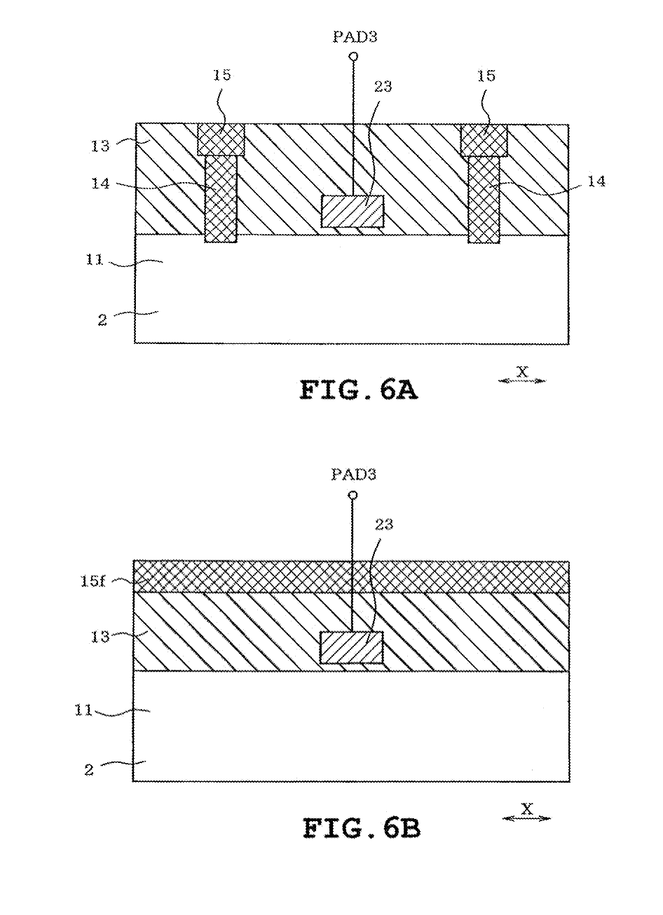

Next, the specific configuration of the evaluation element 21 will be described with reference to FIGS. 5 to 6B. FIG. 5 is an example illustrating a planar layout of the evaluation element 21. FIGS. 6A and 6B are examples of cross-sections taken along lines 6A-6A and 6B-6B, respectively, in FIG. 5.

In this embodiment, the configuration of the evaluation element 1 according to the first embodiment is provided in two levels in the X direction, which are set as an upper first evaluation element portion 1a and a lower second evaluation element portion 1b. The first evaluation element portion 1a and the second evaluation element portion 1b are not connected, and a gate electrode 23 is arranged so as to extend over the element forming region 11 in the Y direction. The gate electrode 23 is disposed on the element forming region 11 with a gate insulating film located therebetween. The gate electrode 23 is extended out to the exterior region of the evaluation element by a wiring pattern, not illustrated, and is connected to the PAD 3 (electrode pad 22).

The basic configuration of the first evaluation element portion 1a and the second evaluation element portion 1b are substantially the same as the evaluation element 1 according to the first embodiment. In the second evaluation element portion 1b, although the connection form of the wiring pattern 15 is somewhat different in portions, the second evaluation element portion 1b has substantially the same layout as the first evaluation element portion 1a with the exception of changes to the connection path. The PAD 1 is connected in series to PAD 2 through the first evaluation element portion 1a and the second evaluation element portion 1b.

In the first evaluation element portion 1a, a wiring pattern 15f is provided instead of the wiring pattern 15e connected to the PAD 2 according to the first embodiment. In the second evaluation element portion 1b, the above-described wiring pattern 15f of the first evaluation element portion 1a is connected, instead of the wiring pattern 15e connected to the PAD 1 according to the first embodiment. The wiring pattern 15f extends in the X direction over the first evaluation element portion 1a and the second evaluation element portion 1b on the upper surface of the insulating film 13 on the gate electrode 23, as illustrated in FIG. 6B.

The second evaluation element portion 1b is also formed with the same configuration or layout as the first evaluation element portion 1a. Between the first evaluation element portion 1a and the second evaluation element portion 1b, the element forming region 11 is connected through the lower portion of the gate electrode 23. Here, by applying a voltage to the gate electrode 23 between the first evaluation element portion 1a and the second evaluation element portion 1b and to the PAD 3, a depletion layer forms on the element forming region 11 directly below the gate electrode 23 and the portion of the element forming region 11 under the gate electrode and thus between the first evaluation element portion 1a and the second evaluation element portion 1b becomes non-conductive and electrically isolates the portion of the element isolation regions 11 on one side of the gate electrode from the portions of the element isolation regions on the other side of the gate electrode. As a result, the contact plugs 14 of the first evaluation element 1a and the second evaluation element 1b are only series connected through the wiring pattern 15f or the like and are not connected through the portions thereof extending under the gate electrode which would, if connected, also connect them in parallel, and in this state the evaluation of the contact plugs 14 for an unopened plug maybe undertaken.

<Process Evaluation of Contact Hole with Evaluation Element>

For the evaluation element 21 configured as above, a probe is brought into contact with PAD 1 to PAD 3 from the outside, and, for example, a positive voltage is applied to the PAD 1, and a lower voltage (for example, 0V) than the PAD 1 is applied to the PAD 2. A depletion layer region is formed on the element forming region 11 directly below the gate electrode 23 on the PAD 3 when a voltage is applied thereto so as to isolate the element forming regions 11 of the first evaluation element 1a from those of the second evaluation element 1b. In this state, the contact plugs 14 of the first evaluation element portion 1a and the second evaluation element portion 1b are connected only in series, via the wiring pattern 15f.

Owing to this, similarly to the first embodiment, the presence of an unopened contact hole 13a extending between the element forming regions 11 and the wiring pattern 15 connected through the contact plugs 14 may be determined.

According to the second embodiment, along with obtaining the same operation effects as the first embodiment, even when three or more contact plugs 14 separated in the X direction contact the same element forming region 11 extending in the X direction, a configuration in which the sides of the element forming regions 11 on either side of the central region thereof (where the gate electrode is located) are disconnected is made possible by providing the gate electrode. Owing to this, a configuration may be adopted in which the first evaluation element portion 1a and the second evaluation element portion 1b are connected in series, and an evaluation of the proper opening condition of numerous contact holes 13a in the area of the evaluation element 21 may be performed.

### Third Embodiment

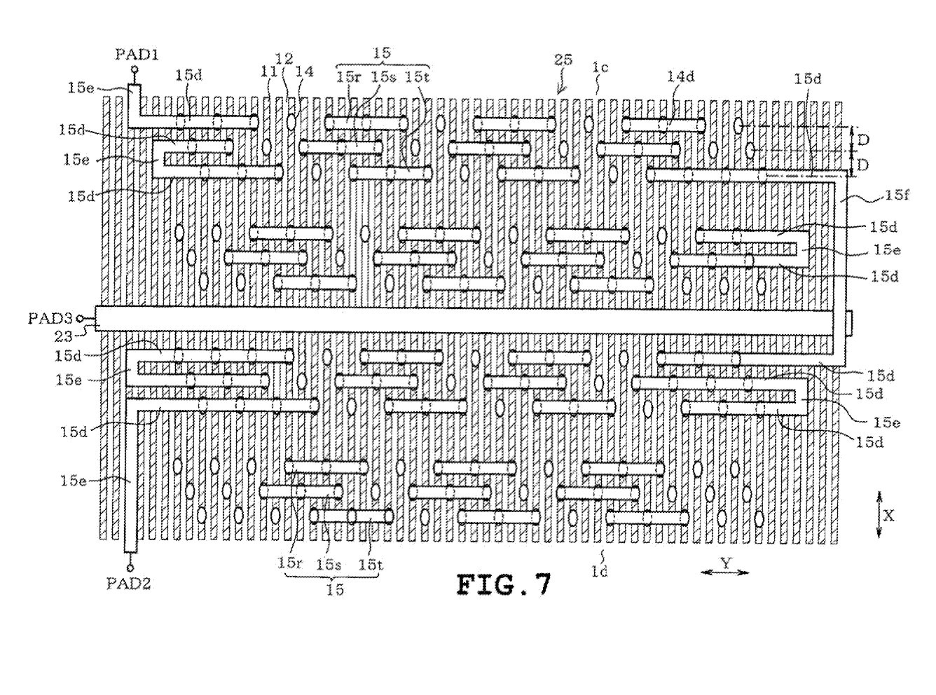

FIG. 7 illustrates a third embodiment. In this embodiment, a configuration maybe adopted in which the wiring pattern 15 of the segments of the second wiring pattern 15 is provided to span three adjacent contact plugs 1415r, 15s, and 15t in the Y direction. In the embodiment, every sixth element forming region 11 is used as a conduction path between the upper and lower wiring patterns on either side of the gate electrode 13, and the spacing between adjacent wiring pattern 15 segments in the Y direction span six gaps between the element forming regions 11.

FIG. 7 is an example of a plan layout of an evaluation element 24. In the embodiment, a first evaluation element portion 1c and a second evaluation element portion 1d that correspond to the first evaluation element portion 1a and the second evaluation element portion 1b according to the second embodiment are provided on both sides with the gate electrode 23 interposed. The first evaluation element portion 1c and the second evaluation element portion 1d are connected by the wiring pattern 15f extending in the X direction and passing over the gate electrode 23.

In the first evaluation element portion 1c, the wiring pattern 15e in the X direction connected to the PAD 1 (electrode pad 4) is connected to the wiring pattern segment 15d extending in the Y direction. The wiring pattern segment 15d is formed so as to extend over and contact three contact plugs 14. The wiring pattern segments 15d of the upper wiring pattern 15r that are adjacent to each other in the Y direction are formed such that one contact plug 14d is interposed therebetween and is not connected to any portion of the wiring pattern 15 but is connected to an element forming region 11, and thus is not evaluated for the opening state thereof. The segments of the upper wiring pattern 15r that are adjacent in the Y direction are similarly formed so as to extend across and thus contact three contact plugs 14. The subsequent segment of the wiring pattern 15r adjacent in the Y direction is formed so as to extend over and contact three contact plugs 14, with one not connected to wiring pattern 15r located in the space between the adjacent segments of the wiring pattern 15r.

The last contact plug 14 on wiring pattern 15d from the left side of the FIG. 7 is connected to the wiring pattern 15d through four contact plugs 14 extending to the lower layer element forming region 11, but again only one of these contact plugs are connected to an element forming region 11 which is connected to another wiring pattern segment through a different contact plug connected therewith. The middle wiring pattern 15s and the lower wiring pattern 15t are formed in the same manner. The three levels of wiring patterns 15r, 15s, and 15t in the first and second element evaluation portions 1c and 1d are connected by a folded-back wiring pattern formed from the wiring pattern 15f in the end portion in the Y direction of each level, and both end portions are set to a state of being connected in series between the PAD 1 and the PAD 2. The second evaluation element portion 1d is formed substantially similarly to the first evaluation element.

Similarly to the second embodiment, by applying a voltage from the PAD 3 to the gate electrode 23, the element forming region 11 of the first evaluation element 1c and the second evaluation element 1d may be electrically isolated from one another by forming a depletion layer in the element forming region 11 directly below the gate electrode 23. As a result, the contact plugs 14 of the first evaluation element 1c and the second evaluation element 1d may be connected only in series via the wiring pattern 15f, or the like, and the presence of unopened contact holes 13 may be determined.

<Process Evaluation of Contact Hole with Evaluation Element>

In the evaluation element 21 configured as above, a probe is brought into contact with PAD 1 to the PAD 3 from the outside, for example, a positive voltage is applied to the PAD 1, and a lower voltage (for example, 0V) than that on PAD 1 is applied to PAD 2. A voltage is applied to PAD 3 such that a depletion layer region is formed in the element forming region 11 directly below the gate electrode 32 the PAD 3. In this state, the first evaluation element portion 1a and the second evaluation element portion 1b are electrically connected in series via the wiring pattern 15f.

Owing to this, the opening state of the contact holes 13a connected between the element forming region 11 and the wiring pattern 15 connected by the contact plugs 14 may be evaluated. Even with such a third embodiment, the same operation effects as the first and second embodiments may be obtained.

In the embodiment, since the contact plugs 14 formed to be adjacent each other on a straight line in the Y direction are not all used as conduction paths, the number of contact plugs 14 devoted to evaluation is reduced. The result becomes equivalent to a sampling inspection of the contact plugs 14. In this case, since the overall series connected conduction path is shorter because fewer paths through contact plugs 14 and element forming regions 11 are provided, the resistance value of the electrical path of the evaluation element becomes lower, and a large current value enabling detection of unopened contact holes 13 may be obtained. Therefore, the precision of evaluation may be increased.

At some locations, at least two contact plugs 14d are arranged on the element forming region 11, and although one thereof is connected to the wiring pattern 15, the other is not connected to a wiring pattern. As a result, this contact plug 14d is not connected in series via the wiring pattern 15 or the like. As a result, even if the contact plug 14d is arranged, the opening state of the contact hole 13a may not be evaluated.

### Fourth Embodiment

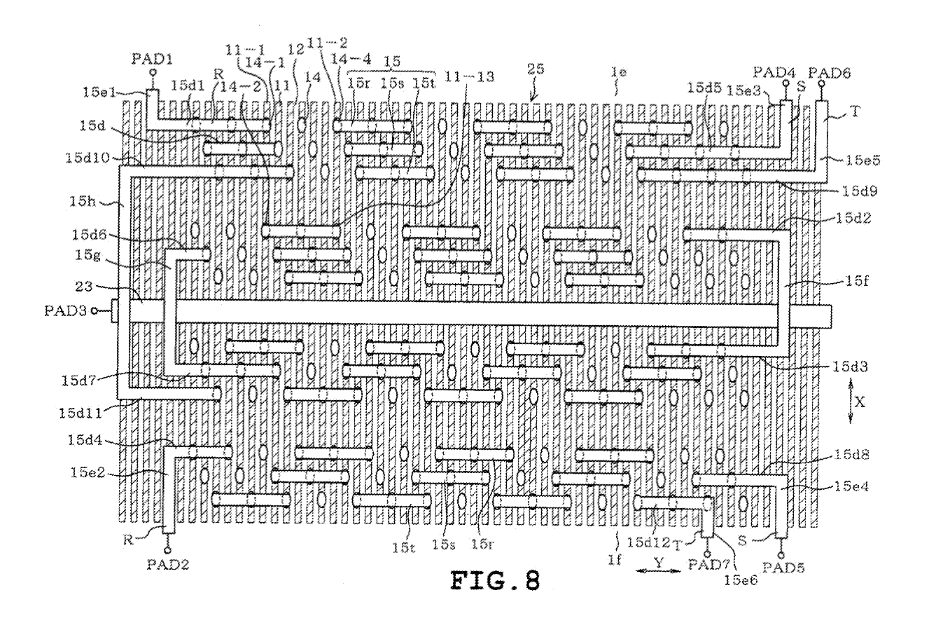

FIG. 8 illustrates a fourth embodiment. In the embodiment, the three levels of wiring patterns 15r, 15s, and 15t are not connected, and thus multiple PADS 1-6 are provided on evaluation element 25 to evaluate each wiring pattern level separately.

FIG. 8 is an example illustrating a plan layout of the evaluation element 25. In the fourth embodiment, a first evaluation element portion 1e and a second evaluation element portion 1f that correspond to the first evaluation element portion 1c and the second evaluation element portion 1d according to the third embodiment are provided on either side of the interposed gate electrode 23. The first evaluation element portion 1e and the second evaluation element portion 1f are connected by the wiring patterns 15f, 15g, and 15h which separately connect each level of segments of the wiring pattern 15 on either side of the gate electrode 23. The conduction path for evaluation is thus split into three paths, which are respectively referred below to as a first conduction path R, a second conduction path S and a third conduction path T. As a result, if an unopened contact opening 13 is detected, the location thereof on the evaluation element may be better understood.

The first conduction path R is a conduction path relating to the unit UN1, the second conduction path S is a conduction path relating to the unit UN2 and the third conduction path T is a conduction path relating to the unit UN3.

The first evaluation element portion 1e and the second evaluation element portion 1f, and the formation pattern of the element forming region 11 that form the first wiring and the contact plugs 14 forming the connection conductors are substantially the same as the configuration according to the second embodiment. In the present embodiment, four electrode pads are additionally provided (not illustrated) in the scribing region 2a of the semiconductor wafer 2, in addition to the electrode pads 4, 5, and 22. The four electrode pads are indicated by PAD 4 to PAD 7.

The first conduction path R will be described. In the first evaluation element portion 1e, a wiring pattern 15e1 in the X direction connected to the PAD 1 is connected to the wiring pattern segment 15d1 extending in the Y direction. The segments of the upper wiring pattern 15r are connected to the wiring pattern 15d via the contact plug 14-1, the element forming region 11, and the contact plug 14-2, which is the same configuration as the third embodiment. However, in the present embodiment, the upper wiring pattern 15r in the lower portion of the first evaluation element 1e is connected to the wiring pattern 15f extending in the X direction without being connected to the middle wiring pattern 15s at the end portion in the X direction. The wiring pattern 15f is connected to the wiring pattern 15d of the second evaluation element portion 1f by extending the wiring pattern 15f over the gate electrode 23, and connected therefrom to the connection pattern of the lower wiring pattern 15t. After connecting to the lower wiring pattern 15t, the segments of the wiring pattern 15f are connected to the wiring pattern 15e2 extending in the X direction from the wiring pattern segment 15d4 extending in the Y direction at the end portion of the wiring portion 15d in the lower part of the evaluation element if in the Y direction, and then connected to the PAD 2.

Similarly, the second conduction path S is described. The middle wiring pattern 15s of the first evaluation element portion 1e is connected to the wiring pattern 15e3 extending in the X direction from the PAD 4, and thus connected to the first segment 15d5 of the wiring pattern 15d extending in the

Y direction. In the first evaluation element portion 1e, the segments of the middle wiring pattern 15s in the upper and lower portions are connected to the element forming region 11 and the contact plugs 14 forming a conduction path therebetween, and the last wiring pattern segment 15d6 is connected to the wiring pattern 15g extending in the X direction from the wiring pattern 15d extending in the Y direction at the end portion in the Y direction thereof so as to pass over the gate electrode 23.

The wiring pattern 15g, where it extends into the second evaluation element portion 1f, is connected to the wiring segment 15d7 of wiring pattern 15d extending in the Y direction corresponding to the middle wiring pattern 15s. The wiring patterns 15g of the middle wiring portion 15s are connected to the wiring patterns 15e spaced in the X direction from the wiring patterns 15d and extending in the Y direction through the element forming regions 11, and are ultimately connected to the PAD 5 where the final wiring pattern segment 15d8 is connected to wiring pattern 15e4.

Furthermore, the third conduction path T will be described. The wiring pattern segment 15d9 of lower wiring pattern 15t of the first evaluation element portion 1e is connected to the PAD 6 through wiring pattern 15e5 extending in the X direction from PAD 6. In the first evaluation element portion 1e, the individual segments of the lower wiring pattern 15t extending across and contacting three contact plugs 14 in the upper and lower portions thereof are connected to the element forming regions 11 and the contact plug 14s thus forming a conduction path therebetween, and connected to the wiring pattern 15h extending in the X direction, from the wiring pattern segment 15d6 extending in the Y direction at the end portion in the Y direction, so as to cross over the gate electrode 23.

The wiring pattern 15h, where it extends into the second evaluation element portion 1f, is connected to the wiring pattern segment 15d11 extending in the Y. The segments of the wiring pattern 15t in the upper and lower portions, in plan view, of the second evaluation element 1f, are connected through the contact plugs 14 and element forming regions 11, and the last segment 15d12 in the lower portion is connected to the wiring pattern 15e6 extending in the X direction therefrom to be to the PAD 7.

Similarly to the third embodiment, by applying a voltage to the gate electrode 23 from the PAD 3, the portion of the element forming region 11 between the first evaluation element 1e and the second evaluation element 1f is made non-conductive, and the portions of the element isolation regions to either side thereof are electrically isolated from one another by forming a depletion layer on the element forming region 11 directly below the gate electrode 23. The contact plugs 14 of the first evaluation element 1e and the second evaluation element 1f are thus connected only in series and evaluated via the wiring patterns 15f, 15g, and 15h, or the like.

<Process Evaluation of Contact Hole with Evaluation Element>

The evaluation element 25 configured as above may evaluate the first, second and third conduction paths R, S and T separately. When evaluating the conduction state of the contact plug 14 connected to the first conduction path R, that is the opening state of the contact hole, a voltage is applied to the PAD 1 to the PAD 3 by bringing a probe into contact therewith. For example, a positive voltage is applied to the PAD 1, and a lower voltage (for example, 0V) than PAD 2 is applied to the PAD 2. A voltage is applied to the PAD 3 such that a depletion layer region is formed on the element forming region 11 directly below the gate electrode 23. In this state, the first evaluation element portion 1e and the second evaluation element portion 1f are electrically connected only in series via the wiring pattern 15f.

Similarly, for evaluation of the second conduction path S, a voltage is applied to the PAD 3 to PAD 5 by bringing a probe into contact. For example, a positive voltage is applied to the PAD4, and a voltage lower than the PAD 4 (for example, 0V) is applied to the PAD 5. A depletion layer region is formed on the element forming region 11 directly below the gate electrode 23 on the PAD 3. For the evaluation of the third conduction path T, a voltage is applied to the PAD 3, PAD 6, and PAD 7 by bringing a probe into contact therewith. For example, a positive voltage is applied to the PAD 6, and a voltage lower than PAD 6 (for example, 0V) is applied to the PAD 7. A depletion layer region is formed on the element forming region 11 directly below the gate electrode 23 on the PAD 3.

Owing to this, the opening state of the contact hole 13a of a portion connected via between the element forming region 11 and the wiring pattern 15 connected by the contact plugs 14 may be evaluated.

Even with such a fourth embodiment, the same operation effects may be obtained as the first to third embodiments. Since the opening evaluation of the contact hole 13a is performed separately for the three first to third conduction paths R, S and T, an evaluation narrowing down in which unit UN an unopened contact hole 13a occurs may be performed.

### Fifth Embodiment

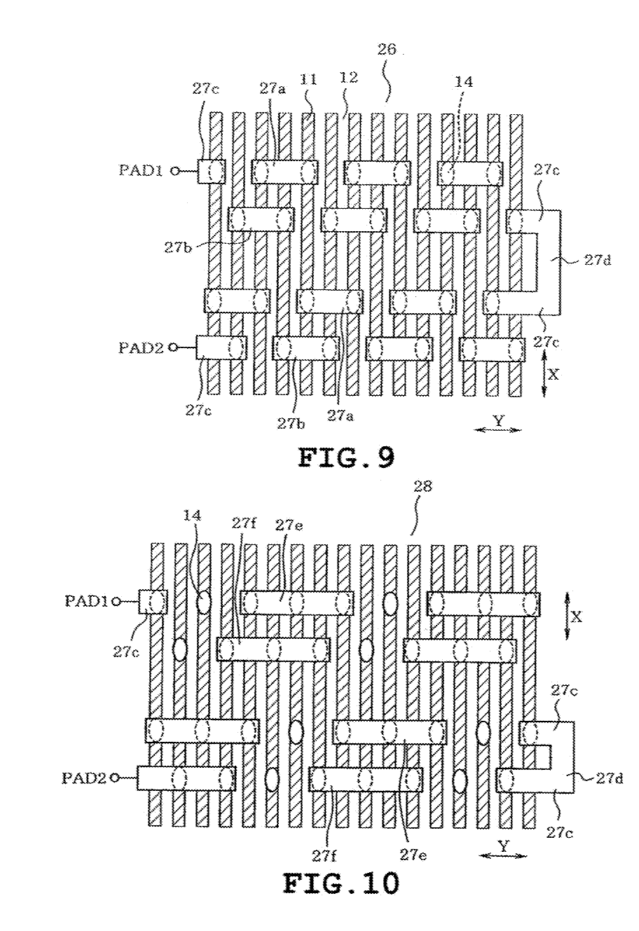

FIG. 9 illustrates a fifth embodiment. In this embodiment, an evaluation element 26 in which the evaluation pattern of the contact plugs 14 is shifted by only two levels in the X direction is illustrated.

FIG. 9 is an example illustrating the plan layout of the evaluation element 26. The contact hole 13a formed so as to penetrate vertically is provided in the interlayer insulating film 13 of the upper surface of the element forming region 11, which is the first wiring. The contact holes 13a extending from adjacent element forming regions are provided at a position shifted by a predetermined distance D (FIG. 2) in the X direction with two holes that are adjacent to each other in the Y direction forming a unit. Owing to this, the contact holes 13a that are adjacent to each other in the Y direction are formed in a location corresponding to every two element forming regions 11. In other words, the contact holes 13a are formed in a state of being alternately shifted by distance D in the X direction on each adjacent element forming region 11. The contact plug 14 is formed as a connection conductor embedded in the contact hole 13a.

A wiring pattern 27 as a second wiring is formed in the Y direction on the upper surface of the interlayer insulating film 13 so as to contact the upper layer of the contact plugs 14. The wiring pattern 27 is formed to include wiring pattern segments which electrically connect the contact plugs 14 adjacent to each other in the Y direction. Since the contact plug 14 locations are shifted in the X direction for every adjacent forming region 11, the contact plugs are formed as four rows in the Y direction with a single element forming region 11 interposed between adjacent contact plugs 14 in each row. Accordingly, the segments of the wiring pattern 27 is formed so as to connect two contact plugs 14 that are adjacent to each other in the Y direction for every three element forming regions 11.

Since the wiring pattern 27 is formed in the Y direction with respect to each contact plug 14 shifted in the X direction, wiring patterns 27a and 27b are disposed in two levels. The two levels of wiring patterns 27a and 27b shifted in the X direction are made the upper level and lower level. The contact plugs 14 are electrically connected via the element forming region 11 to interconnect connect the wiring pattern segments in wiring patterns 27a in the upper and lower portions of the evaluation element 26, and to interconnect the wiring pattern segments 27b in the upper and lower portions of the evaluation element 26, and wiring patterns 27 d and 27e connect the upper wiring pattern 27b to the lower wiring pattern 27a.

The PAD 1 (electrode pad 4) and the PAD 2 (electrode pad 5) are connected to both ends of the evaluation element 26. The conduction path between the PAD 1 and PAD 2 is connected to the contact plug 14 arranged at the end portion in the Y direction from the PAD 1 via a wiring pattern 27c. The contact plug 14 is connected to the upper wiring pattern 27a on the upper layer from the contact plug 14 formed on the other end portion in the X direction via the element forming region 11 on the lower layer. The upper wiring pattern 27a is connected to the contact plug 14 formed on the second element forming region 11 positioned with being adjacent to each other in the Y direction, and therefrom is connected to the upper wiring pattern 27a on the upper layer via the contact plug 14 formed on the other in the X direction through inside the element forming region 11 on the lower layer.

The two levels of wiring patterns 27a and 27b in the lower portion of FIG. 9 are similarly connected by alternately connecting the element forming region 11 to the contact plug 14, and electrical connection is finally established from the PAD 1 to the PAD 2.

<Process Evaluation of Contact Hole with Evaluation Element>

For the evaluation element 26 configured as above, a probe is brought into contact with PAD 1 and PAD 2 from the outside, and, for example, a positive voltage is applied to the PAD 1, and a negative voltage is applied to the PAD 2. Owing to this, the current flowing between the PAD 1 and the PAD 2 is monitored. Owing to this, evaluation of the presence of an unopened contact hole 13a may be performed similarly to the first embodiment.

According to the fifth embodiment, even in a configuration in which the contact plugs 14 are disposed alternately with being shifted by the distance D in the X direction between the adjacent element forming regions 11, the same operation effects as the first embodiment may be obtained.

### Sixth Embodiment

FIG. 10 illustrates a sixth embodiment. This embodiment is a layout with the third embodiment incorporated into the fifth embodiment.

Even with the sixth embodiment, evaluation of the unopening of the contact holes 13a may be performed by sampling similarly to the third embodiment.

### Other Embodiment

The following modifications are possible in addition to those described in the embodiments.

The embodiment may be applied to a configuration using the first wiring and the second wiring as any conduction path in which a semiconductor layer is used. In this case, the embodiment is applicable to a combination that sets the semiconductor substrate (wafer) as the first wiring, and a semiconductor layer formed on an insulating film as the second wiring, and a combination that seta semiconductor layer formed on the insulating film as the first wiring, and further sets the semiconductor layer formed via the insulating film as the second wiring.

The embodiment may be applied to a configuration using the first wiring and the second wiring as any conduction path in which a metal layer is used. In this case, the embodiment is applicable to a combination in which a metal layer formed on an insulating film is set as the first wiring, and a metal layer formed via the insulating film is set as the second wiring.

The embodiment is also applicable to a configuration using the metal layer as the first wiring and the semiconductor layer formed via the insulating film as the second wiring.

In the second embodiment (the same applies to the third and fourth embodiments), although an example is illustrated in which the first evaluation element portion 1a and the second evaluation element portion 1b are connected by the wiring pattern 15f, an evaluation element may be configured in which adjacent evaluation element portions are additionally provided by configuring additional gate electrodes spaced and parallel to one another.

The wiring pattern 15 as the second wiring that connects between the contact plugs 14 arranged in the Y direction may also adopt a form in which the wiring patterns are connected to a greater plurality of contact plugs 14, in addition to a form in which neighboring wiring patterns are connected to one another as in the first embodiment and the second embodiment, and a form in which the wiring patterns are connected skipping one as in the third embodiment.

In a configuration in which the contact plugs 14 are disposed by being shifted by the distance D in the X direction between adjacent element forming regions 11, although cases of three units and two units are given as examples, the embodiment is also applicable to a configuration disposed with being shifted by said numbers or more.

A configuration in which the first to third conduction paths are provided as in the fourth embodiment and the conduction paths are separately evaluated may also be applied to the configuration of the second embodiment.

The configuration according to the second embodiment is also applicable to the configuration of the fifth embodiment.

The configuration according to the third embodiment is also applicable to the configuration of the sixth embodiment.

The embodiment may be applied generally to a semiconductor device including a configuration in which a line-and-space wiring pattern and a contact thereto are formed or a device with a similar configuration thereto.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An evaluation element comprising:
a plurality of first wirings extending in a first direction;
connection conductors, each connection conductor electrically contact a single one of the first wirings; and
a plurality of second wirings extending in a second direction that crosses the first direction and electrically contacts the connection conductors contacting the first wirings,
wherein the connection conductors are provided in at least two separated positions on the same first wiring and
the plurality of second wiring is positioned such that a series electrical connection is established, through the connection conductors and the first wirings, between one second wiring and another second wiring.

2. The evaluation element according to claim 1,
wherein the second wirings comprise a plurality of segments extending in the second direction, and each segment is isolated from every other segment and interconnects connection conductors along a row of connection conductors.

3. The evaluation element according to claim 2,
wherein the segments of the second wirings interconnect at least three connection conductors.

4. The evaluation element according to claim 2,
wherein one of at least two segments of the second wirings, among the plurality of second wirings is connected to the connection conductor, and the other is connected to an electrode pad against which a contact probe may be contacted.

5. The evaluation element according to claim 1,
wherein the connection conductors are connected to both ends of the second wiring.

6. The evaluation element according to claim 1,
wherein the connection conductors positioned on adjacent first conductors are spaced apart by a predetermined gap in the first direction.

7. The evaluation element according to claim 6, wherein
the plurality of connection conductors and a plurality of second wiring are configured as a first unit and a second unit extending in the second direction and spaced apart in the first direction, and
a third wiring is provided that connects one connection conductor of the plurality of connection conductors of the first unit with one connection conductor of the plurality of connection conductors of the second unit.

8. The evaluation element according to claim 1,
wherein the connection conductor has an oval shape in cross section and the major axis direction of the oval shape is the first direction.

9. The evaluation element according to claim 1,
wherein a width of the first wiring in the second direction is less than or equal to the exposure limit dimension of an optical exposure device.

10. The evaluation element according to claim 9,
wherein a width of the second wiring in the first direction is greater than or equal to the exposure limit of the optical exposure device.

11. The evaluation element according to claim 1, wherein
the first wirings are provided by separating a surface layer of a semiconductor substrate using a linear element separating insulating film formed along the first direction, and
a gate electrode positioned adjacent to, and crossing the first wirings.

12. The evaluation element according to claim 11, further comprising:
an electrode pad for applying a voltage to the gate electrode for electrically disconnecting opposed ends of the first wiring.

13. A wafer, comprising:
a plurality of semiconductor devices disposed in a matrix form with a predetermined gap therebetween; and
an evaluation element provided in a scribing region between adjacent semiconductor devices, the evaluation element including:
a plurality of first wirings extending in a first direction;
connection conductors, each connection conductor electrically contact a single one of the first wirings; and
a plurality of second wirings extending in a second direction that crosses the first direction and electrically contacts the connection conductors contacting the first wirings,
wherein the connection conductors are provided in at least two separated positions on the same first wiring, and the plurality of second wiring is positioned such that a series electrical connection is established, through the connection conductors and the first wirings, between one second wiring and another second wiring.

14. The wafer according to claim 13,
wherein the second wirings comprise a plurality of segments extending in the second direction, and each segment is isolated from every other segment and interconnects connection conductors along a row of connection conductors.

15. The wafer according to claim 14,
wherein the segments of the second wirings interconnect at least three connection conductors.

16. The wafer according to claim 15, wherein at least one of the three connection conductors interconnected by the second wiring segments are not electrically connected, through an element forming region and another connection conductor, to a different second wiring segment.

17. A method of forming an evaluation element for evaluating the opening condition of an opening in a film layer to an underlying feature on a semiconductor substrate which has a dimension below the dimensional limits of an optical exposure device, comprising:
providing a plurality of first wirings extending in a first direction having a width dimension less than the dimensional limits of an optical exposure device;
providing an insulating layer thereover;
providing openings through the insulating layer configured to extend to the individual first wirings, wherein at least two openings are configured to extend, in a spaced apart relationship, to each of the first wirings of a plurality of the first wirings;
providing a conductive material filling the openings through the insulating layer; and
providing a second wiring comprising a plurality of wiring segments, wherein at least a first wiring segment is connected to a second wiring segment via different connection conductors and a single one of the first wirings.

18. The method of claim 17, further comprising:
positioning the connection conductors in a plurality of rows; and
positioning the individual segments of the second wirings to contact at least two adjacent connection conductors in a row of conduction connectors.

19. The method of claim 18, further comprising:
providing a gap between adjacent segments of the first wiring layer contacting at least two adjacent connection conductors in a row of connection conductors.

20. The method of claim 18, wherein the segments of the second wiring contacting the connection conductors of a first row of the plurality of rows of connection conductors are electrically connected in series to a second row of the plurality of rows of connection conductors through the first wirings.
